(19) United States
(12) Patent Application Publication
(10) Pub. No.: US 2021/0372667 A1
(43) Pub. Date: Dec. 2, 2021

(54) METHOD AND SYSTEM FOR DETECTING INEFFICIENT ELECTRIC WATER HEATER USING SMART METER READS

(71) Applicant: GRID4C Ltd., Tel Aviv (IL)

(72) Inventors: Eran SAMUNI, Giv'atayim (IL); Eran COHEN, Ramat Gan (IL); Alexander ZAK, Jerusalem (IL); Noa RUSCHIN RIMINI, Ra'anana (IL)

(21) Appl. No.: 16/883,459

(22) Filed: May 26, 2020

(51) Int. Cl. F24H 9/20; G01R 22/06; G01M 99/00; F24H 9/00

(52) U.S. Cl. CPC F24H 9/2014; F24H 9/0005; G01M 99/005; G01R 22/061

(57) ABSTRACT

A method for identifying an electric water heater having excessive and abnormal electricity consumption for detecting inefficiency or even a malfunction comprising the following steps:
The present invention provides a method for automatic detection of inefficient household heater within a group of monitored households, implemented by a server module and a plurality of household client modules, wherein each of said a server module and plurality of household client modules comprising one or more processors, operatively coupled to non-transitory computer readable storage devices, on which are stored modules of instruction code, wherein execution of said instruction code by said one or more processors implements the following actions:
   acquiring data relating to each monitored household, including at least part of: environmental conditions, power consumption of each water heater, household profile parameters, and household residents' profile parameters;
   detect events wherein the water heater's power consumption (P) surpasses a predefined threshold (Pth), and henceforth label said detected events as “water heater activation” events; For each house (i) in the training set, and per each consumption day (d), define a binary label L_{id}. Said label marks the water heater's activity as either ‘Normal’ or ‘Abnormal’ per house i and day d. Initialize all labels as ‘normal
   training a machine learning algorithm, to create at least one classification model, wherein all monitored households are classified according to said acquired data and parameters; and Using the Activation Events Classification Model after the training stage, to predict the binary label, L_{id}, or number activation per day that a specific household (i), from beyond the household training set has surpassed a predefined number of water heater activation events (n) within a day.

### FIELD OF THE INVENTION

The present invention generally relates to the field of monitoring electronic appliances, and particularly to the field of automatic detection of household appliance malfunction of inefficiency.

### BACKGROUND ART

There are numerous water-consuming appliances and systems in residential and commercial installations one of which is a water heater. The detection of an electric water heater that has excessive and abnormal electricity consumption is essential for the purpose of closing off the supply of water and energy and preventing a considerable damage in the case of a malfunctioned water heater.

### SUMMARY OF THE PRESENT INVENTION

A method for identifying an electric water heater having excessive and abnormal electricity consumption for detecting inefficiency or even a malfunction comprising the following steps:

The present invention provides a method for automatic detection of inefficient household heater within a group of monitored households, implemented by a server module and a plurality of household client modules, wherein each of said a server module and plurality of household client modules comprising one or more processors, operatively coupled to non-transitory computer readable storage devices, on which are stored modules of instruction code, wherein execution of said instruction code by said one or more processors implements the following actions:
acquiring data relating to each monitored household, including at least part of: environmental conditions, power consumption of each water heater, household profile parameters, and household residents' profile parameters;
detect events wherein the water heater's power consumption (P) surpasses a predefined threshold (Pth), and henceforth label said detected events as “water heater activation” events; For each house (i) in the training set, and per each consumption day (d), define a binary label L_{id}. Said label marks the water heater's activity as either ‘Normal’ or ‘Abnormal’ per house i and day d. Initialize all labels as ‘normal
training a machine learning algorithm, to create at least one classification model, wherein all monitored households are classified according to said acquired data and parameters; and
Using the Activation Events Classification Model after the training stage, to predict the binary label, L_{id}, or number activation per day that a specific household (i), from beyond the household training set has surpassed a predefined number of water heater activation events (n) within a day;
   The present invention provides a method for automatic detection of inefficient household water heater within a group of monitored households, implemented by a server module and a plurality of household client modules, wherein each of said server module and plurality of household client modules comprising one or more processors, operatively coupled to non-transitory computer readable storage devices, on which are stored modules of instruction code, wherein execution of said instruction code by said one or more processors implements the following actions:
   acquiring data related to each monitored household for generating a training set, including at least one of environmental conditions, power consumption of each water heater, power consumption of each household, household profile parameters, and household residents' profile parameters; and
   for each house (i) in the training set, and per each pre-defined period (d), defining a the water heater's activity as either ‘Normal’ or ‘Abnormal’ per house i and day d, based on statistic data water heater activity
   training a machine learning algorithm to create at least one:
   classification model for predicting the water heater's activity as either ‘Normal’ or ‘Abnormal’, wherein all monitored households are classified according to said acquired data and parameters; or
   regression model for predicting the water heater's activity duration and times, wherein all monitored households are determent according to said acquired data and parameters;
   detecting inefficient household water heater(s), after the training period using the regression or Classification Model to, by predicting the water heater activity as normal or abnormal based on acquired data including at least one of environmental conditions, power consumption of the total household, household profile parameters, and household residents' profile parameters
   According to some embodiments of the present invention defining activity as normal or ab normal is based on comparison of the given house to other related house with in the house cluster, wherein cluster is define by houses that are similar houses in the given house vicinity that are mostly similar to the house profile, consumption load and other criteria as house size and appliance ownership
   According to some embodiments of the present invention the determination of water heater's activity as either ‘Normal’ or ‘Abnormal is based on “Activation Events” Neural Network detecting events by labeling water heater for each house (i) in the training set, and per each consumption day (d), defining a binary label L_{id}, said label marks the water heater's activity as either ‘Normal’ or ‘Abnormal’ per house i and day
   According to some embodiments of the present invention the determination of water heater's activity as either ‘Normal’ or ‘Abnormal is based on Percentage Water-heater Activation” (PWA) Neural Network model to predict the percentage working hours of the water heater, wherein the water heater's power consumption (P) surpasses a predefined threshold (Pth), and henceforth label said detected events as “water heater activation” events;
   According to some embodiments of the present invention integrating prediction results of the classification the events detection classification and a PWA classification model to detect the inefficient household heater.
   According to some embodiments of the present invention said data obtainable for use with the Activation Events Classification Model comprises at least one of:
      (a) total household power consumption, from the household power meter interface
      (b) water heater power consumption, from the water heater agent module
      (c) environmental data from the data acquisition module
      (d) day of week and month of the year from the data acquisition module
      (e) cooling day and heating day indication from the data acquisition module
   According to some embodiments of the present invention said predefined period of time is 15 minutes.
   According to some embodiments of the present invention the “Percentage Water-heater Activation” (PWA) Neural Network model receives as input a predefined sliding window period of time of total household power consumption, and determine whether the water heater has been activated during said sliding window period.
   According to some embodiments of the present invention said data obtainable for use with the “Percentage Water-heater Activation” (PWA) Neural Network model comprises at least one of:
   (a) total household power consumption, from the household power meter interface
   (b) environmental data from the data acquisition module
   (c) day of week and month of the year from the data acquisition module and
   (d) cooling day and heating day indication from the data acquisition module
   According to some embodiments of the present invention if indications from both the Activation Events Classification model and the PWA classification model are not abnormal, then, (a) retrieving outcome of number of peaks from the activation events classification model and number of working hours of the water heater from the PWA classification model, (b) calculating normalized score for each model outcome based on to be normalization to standard normal distribution, (c) calculating integrated score which is normalized Score of both models, (d) calculating corresponding percentile of the integrated score based on history/training data of clusters of houses; and (e) for houses having percentile above pre-determined percentage related to it's peers, notifying relevant stake holders regarding the probability of a malfunctioning or inefficient water heater.
   The present invention provides a system for automatic detection of inefficient household water heater within a group of monitored households, comprising at least one server module and a plurality of household client modules, wherein each of said server module and plurality of household client modules comprising one or more processors, operatively coupled to non-transitory computer readable storage devices, on which are stored modules of instruction code, wherein the module comprise:
      Data acquisition module for acquiring data related to each monitored household for generating a training set, including at least one of environmental conditions, power consumption of each water heater, power consumption of each household, household profile parameters, and household residents' profile parameters; and
      training module for each house (i) in the training set, and per each consumption day (d), defining a the water heater's activity as either ‘Normal’ or ‘Abnormal’ per house i and day d, based on statistic data water heater activity and training a machine learning algorithm to create at least one classification model for predicting the water heater's activity as either ‘Normal’ or ‘Abnormal’, wherein all monitored households are classified according to said acquired data and parameters;
      prediction module for detecting inefficient household water heater(s), after the training period using the Classification Model to, by predicting the water heater activity as normal or abnormal based on acquired data including at least one of environmental conditions, power consumption of each household, household profile parameters, and household residents' profile parameters and weather conditions.
   According to some embodiments of the present invention the determination of water heater's activity as either ‘Normal’ or ‘Abnormal is based on comparison of the given house to other related house with in the house cluster, wherein cluster is define by houses that are similar houses in the given house vicinity that are mostly similar to the house profile, consumption load and other criteria as house size and appliance ownership.
   According to some embodiments of the present invention the determination of water heater's activity as either ‘Normal’ or ‘Abnormal is based on “Activation Events” Neural Network detecting events by labeling water heater for each house (i) in the training set, and per each consumption day (d), defining a binary label L_{id}, said label marks the water heater's activity as either ‘Normal’ or ‘Abnormal’ per house i and day d.
   According to some embodiments of the present invention the determination of water heater's activity as either ‘Normal’ or ‘Abnormal is based on Percentage Water-heater Activation” (PWA) Neural Network model to predict the percentage working hours of the water heater, wherein the water heater's power consumption (P) surpasses a predefined threshold (Pth), and henceforth label said detected events as “water heater activation” events;
   According to some embodiments of the present invention are integrated prediction results of the classification the events detection classification and a PWA classification model to detect the inefficient household water heater.
   According to some embodiments of the present invention said data obtainable for use with the Activation Events Classification Model comprises at least one of:
      (f) total household power consumption, from the household power meter interface
      (g) water heater power consumption, from the water heater agent module training data set [.
      (h) environmental data from the data acquisition module
      (i) day of week and month of the year from the data acquisition module
      (j) cooling day and heating day indication from the data acquisition module
   According to some embodiments of the present invention said predefined period of time is 15 minutes.
   According to some embodiments of the present invention the “Percentage Water-heater Activation” (PWA) Neural Network model receives as input a predefined sliding window period of time of total household power consumption, and determine whether the water heater has been activated during said sliding window period.
   According to some embodiments of the present invention said data Obtainable for use with the “Percentage Water-heater Activation” (PWA) Neural Network model comprises at least one of;
   (a) total household power consumption, from the household power meter interface
   (b) environmental data from the data acquisition module
   (c) day of week and month of the year from the data acquisition module and
   (d) cooling day and heating day indication from the data acquisition module
   According to some embodiments of the present invention the system further comprises a decision module, wherein if indications from both the Activation Events Classification model and the PWA classification model are not abnormal, said decision module (a) retrieves outcome of number of peaks from the activation events classification model and number of working hours of the water heater from the PWA classification model, (b) calculates normalized score for each model outcome by normalization to standard normal distribution, (c) calculates integrated score which Sums-up the normalized Score of both models, (d) calculates corresponding percentile of the integrated score based on history/training data of clusters of houses; and (e) for houses having percentile above X % relative to its peers notifies relevant stake holders regarding the probability of a malfunctioning or inefficient water heater.
   According to some embodiments of the present invention the method the step of checking the existence of water heater pre-processing groups of households of historical consumption of water heater based actual measurement performed by sensors associated with said water heater in relation to profile of household including characteristics of the household and/or lifestyle of the occupant and environmental time dependent parameters, and determining the probability of said water heater at the surveyed household based on identified profile parameters and actual behavior pattern of the analyzed household based on sampled measurement in relation to actual time dependent environmental parameters of the relevant time period, by processing identified statistical correlations between presence of appliances at each household and 1) household profiles parameters, 2) household actual periodic consumption pattern 3) household actual periodic consumption pattern in relation to environmental time dependent parameters.

### BRIEF DESCRIPTION OF THE DRAWINGS

For a better understanding of various embodiments of the invention and to show how the same may be carried into effect, reference will now be made, purely by way of example, to the accompanying drawings in which like numerals designate corresponding elements or sections throughout.

With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice. In the accompanying drawings:

FIG. 1 presents a block diagram depicting an overview of a first model in accordance with some embodiments of the present invention.

FIG. 2 presents a block diagram depicting an overview of a second model in accordance with some embodiments of the present invention.

FIGS. 3A&B present high-level overviews of the models of FIGS. 1 & 2.

FIG. 4 is a flow diagram, depicting the function of a data acquisition module according to some embodiments of the present invention.

FIG. 5 is a flow diagram, depicting the function of a data preprocessing module according to some embodiments of the present invention.

FIG. 6 is a flow diagram, depicting the function of an activation events training module of the first model according to some embodiments of the present invention.

FIG. 7 is a flow diagram, depicting the function of the activation events prediction module of the first model according to some embodiments of the present invention.

FIG. 8 is a flow diagram, depicting the function of the Percentage Water heater Active (PWA) training module of the second model according to some embodiments of the present invention.

FIG. 9 is a flow diagram, depicting the function of the Percentage Water-heater Active (PWA) prediction module of the second model according to some embodiments of the present invention.

FIG. 10 is a flow diagram, depicting the functionality of the decision module according to some embodiments of the present invention.

### DETAILED DESCRIPTION OF THE DRAWINGS

Two models for the detection of an electric water heater that has excessive and abnormal electricity consumption are suggested in the present invention, a first model in accordance with some embodiments of the present invention, and a second model in accordance with other embodiments of the present invention.

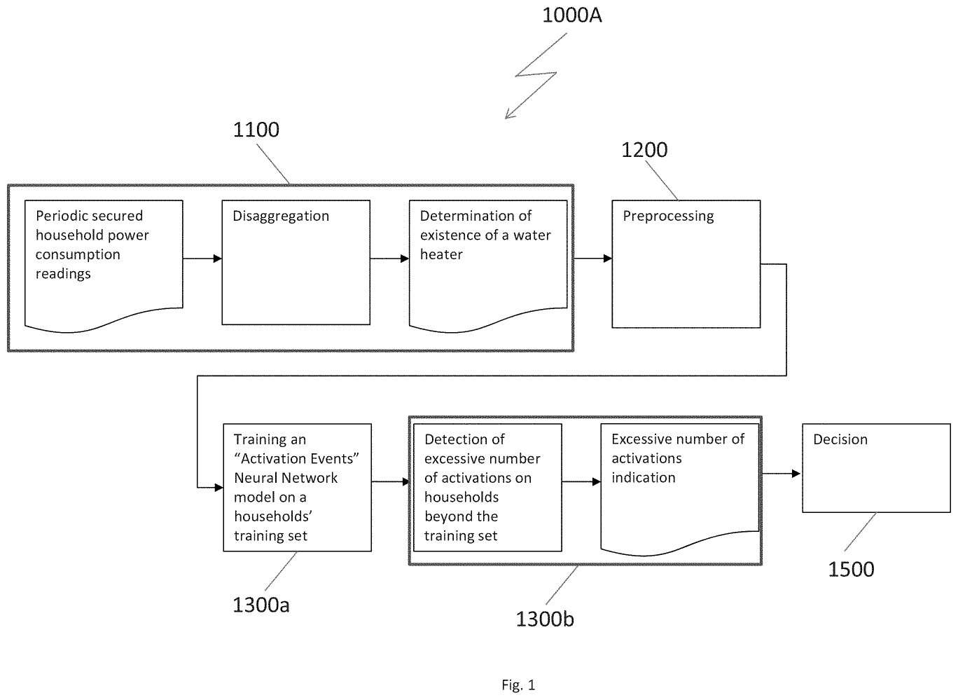

FIG. 1 presents a block diagram depicting a first model 1000A in accordance with some embodiments of the present invention. First model 1000A comprises the following steps:
Data acquisition 1100 which includes:
   Periodic secured household power consumption readings;
   Disaggregation;
   Determination of existence of a water heater;
Preprocessing 1200.
Training an “Activation Events” 1300A using a Neural Network model on a household' training set.
Prediction of activation events 1300B which includes:
   Detection of excessive number of activations on households beyond the training set; where the number of activations is determined dynamically based on learning process for different temperatures Indication of excessive number of activations;
and
Decision.

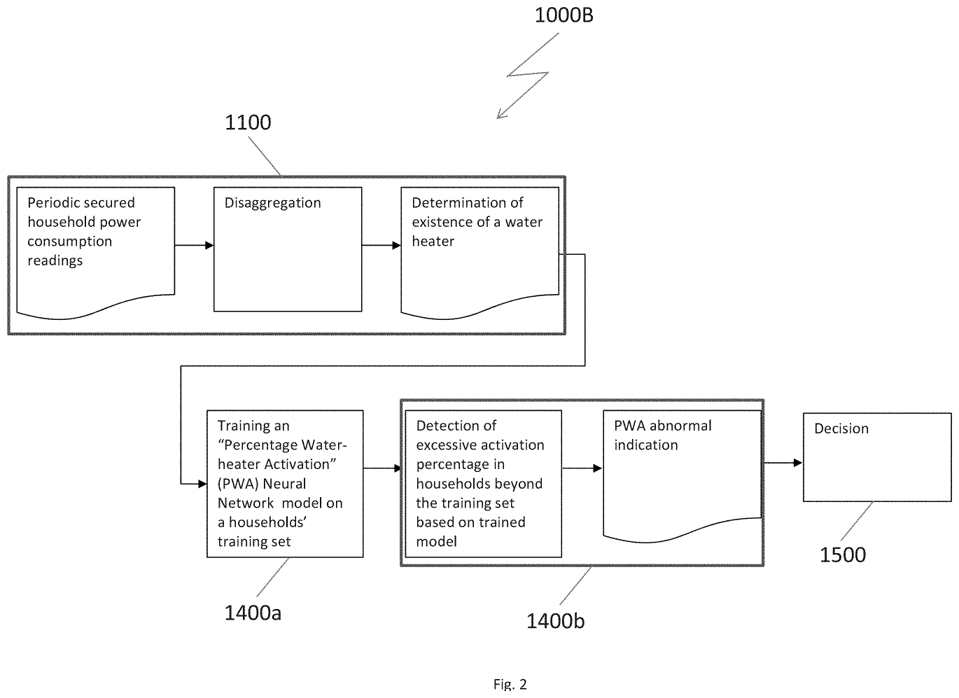

FIG. 2 presents a block diagram depicting a second model 1000B in accordance with some embodiments of the present invention. Second model 1000B comprises the following steps:
Data acquisition 1100 which includes:
   Periodic secured household power consumption readings;
   Disaggregation;
   Determination of existence of a water heater;
Activation event training 1400A—training a “Percentage Water heater Activation” (PWA) Neural Network model on a households' training set.
Prediction of activation events 1400B which includes:
   Detection of excessive activation percentage in households beyond the training set based on trained model; and
   PWA abnormal indication;
and
Decision.

The existence of water heater can be achieved using the method described in patent application no. us 20190034817, as summarized bellow.

The present invention provides a method for determining the presence of an appliance such as electronic water heater within a surveyed household, based on periodic surveying of the household's electric meter.

The method comprising the steps of:
pre-processing groups of households of historical consumption of appliances based actual measurement performed by sensors associated with said appliances in relation to profile of household including characteristics of the household and/or lifestyle of the occupant and environmental time dependent parameters, and
determining the probability of each appliance presence and specifically water heater at the surveyed household based on identified profile parameters and actual behavior pattern of the analyzed household based on sampled measurement taken at predefined discrete time periods such 15 minutes in relation to actual time dependent environmental parameters of the relevant time period, by processing identified statistical correlations between presence of appliances at each household and 1) household profiles parameters, 2) household actual periodic consumption pattern 3) household actual periodic consumption pattern in relation to environmental time dependent parameters.

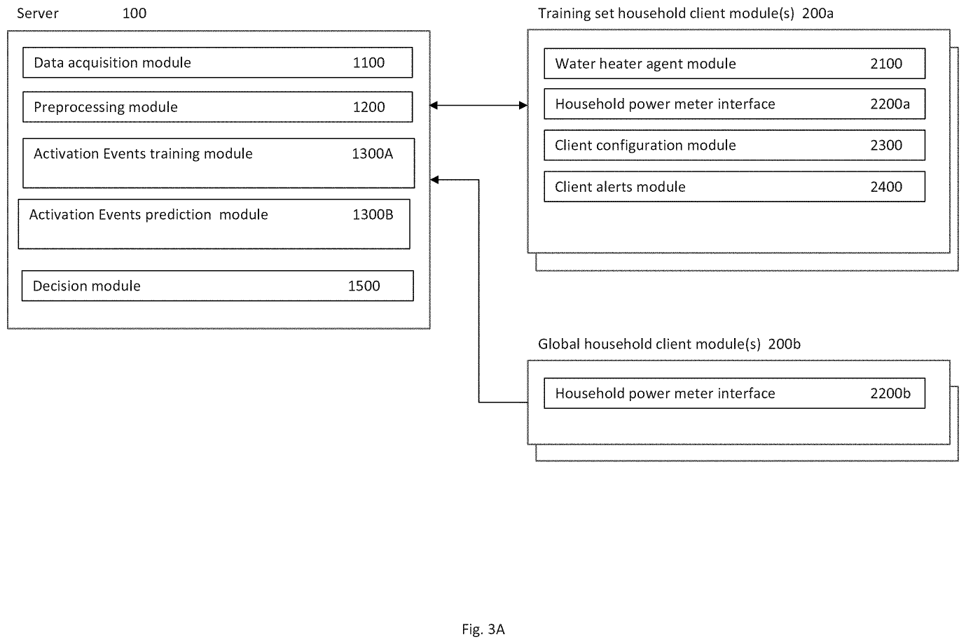

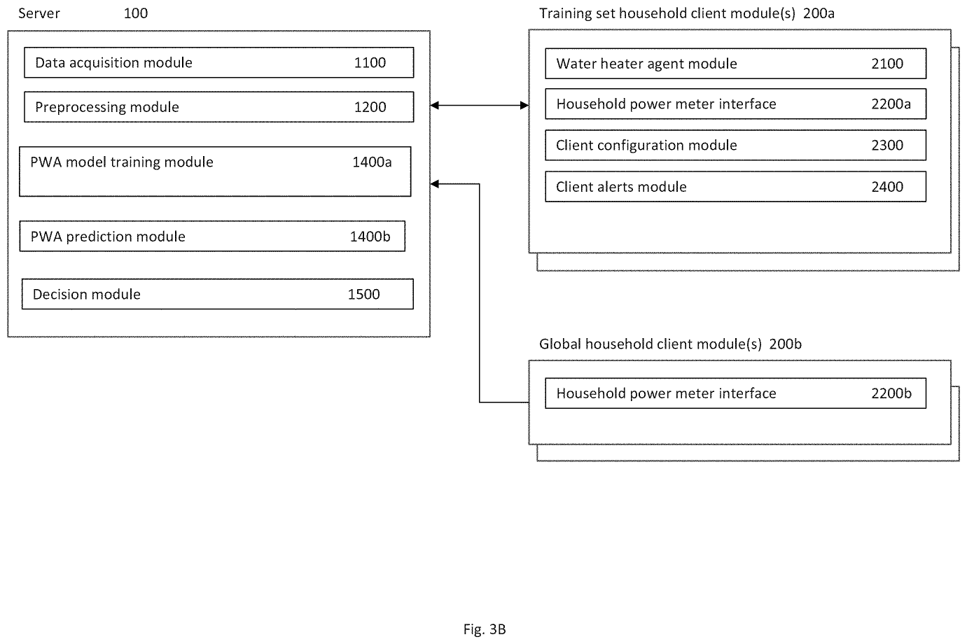

FIGS. 3A&B present high-level overviews of first model 1000A and second model 1000B of FIGS. 1 & 2.

In both models 1000A&B the training set household client 200a and the global household client 200b are modules implemented in software or hardware or any combination thereof, installed at the location of monitored households.

Modules 200a & 200b are configured to interface the server module 100 using any type of wired or wireless data communication standard (e.g. LAN, WAN, WiFi, GSM, 3GPP, LTE etc.), and convey to the server 100 data pertaining to a specific household. This data includes at least one of: the household's properties, the household's overall power consumption, concurrent temperature measurements, and data relating to water heater installed therein.

The training set household client 200a is comprised of at least one of the following sub modules:
Water heater agent module 2100,
Household power meter interface 2200a,
Client configuration module 2300, and
Client alerts module 2400.

The global household client 200h is comprised of the following sub module:
Household power meter interface 2200b

The water heater agent module 2100, acquires data relating to at least one of:
Water heater electric heating activation time; and
Water heater thermostat convenience temperature settings;

The Household power meter interface 2200a, acquires the power consumption of the household over time. According to some embodiments, the Household power meter interface 2200a obtains household power consumption readings every 15/30/60 minutes from a smart household power meter.

The client configuration module 2300 provides an interface for introducing household-specific parameters. These parameters include at least one of:
the water heater properties (e.g. make and model);
residents' profile parameters (e.g. number of residents, household occupancy throughout the day).

The client alerts module 2400 provides an interface for receiving alerts regarding suspected inefficiency of the water heater, according to the logic explained further below.

The server 100 is a module implemented in software or hardware or any combination thereof, configured to interface a plurality of household client modules 200a & 200b, according to some embodiments. The server 100 obtains from each of the plurality of household client modules 200a & 200b data pertaining to each respective household, said data including at least part of:
Water heater electrical heating activation time;
Water heater thermostat convenience temperature settings;
Frequent regular household power consumption readings;
Optionally reading of water flow out and/or in from the water tank;
The number of times the water heater reheats the water across the day\week\month; distinguish between reheating of the same water and new water coming in the tanks based on water flow reading;
Water heater properties (e.g.: make, model, nominal power consumption),
Indoor temperature; and
Resident profile parameters.

According to some embodiments, the server module 100 also communicates with an administrative client module (not shown), which provides an administrative interface for system configuration, real-time alerts and production of historical reports.

The server module 100 includes several sub modules for analyzing said obtained data, identifying specific water heaters as efficient or inefficient, and alerting against suspected conditions of inefficiency or malfunction.

In first model 1000A, the sub-modules include at least one of the following:
The data acquisition module 1100,
The data preprocessing module 1200,
The activation events training module 1300a,
The activation events prediction module 1300b, and
Decision module 1500

In second model 1000B, the sub-modules include at least one of the following:
The data acquisition module 1100,
The data preprocessing module 1200,
PWA model training module 1400a,
PWA prediction module 1400b, and
Decision module 1500.

The data acquisition module 1100 accumulates real-time data from multiple private client modules, and stores it in a database for further processing.

The data preprocessing module 1200 applies various algorithms to produce explanatory features such as:
Household Efficiency Score;
Water heater Linear Coefficient; and
⋅

The activation events training model 1300a applies machine learning algorithms on households within the training group, to produce the water heater efficiency regression model, distinguishing between ‘Efficient’ and ‘Inefficient’ households within the household training group, as elaborated further below.

The activation events prediction module 1300b applies the water heater efficiency regression model to households within the general group of monitored households (i.e. beyond the household training group), and classifies whether the water heater installed within had an abnormal number of activations, which can indicate an inefficiency or a malfunction.

The PWA model training module 1400 applies machine learning algorithms on households within the training group, to produce the PWA (percentage water heater active) regression model, predicting the percentage of working hours of the water heater, as elaborated further below.

The PWA prediction module 1400B applies the PWA model to households within the general group of monitored households (i.e. beyond the household training group), and predicts the percentage of time the water heater was active

The decision module provides an alternative decision procedure which combines the out of both models.

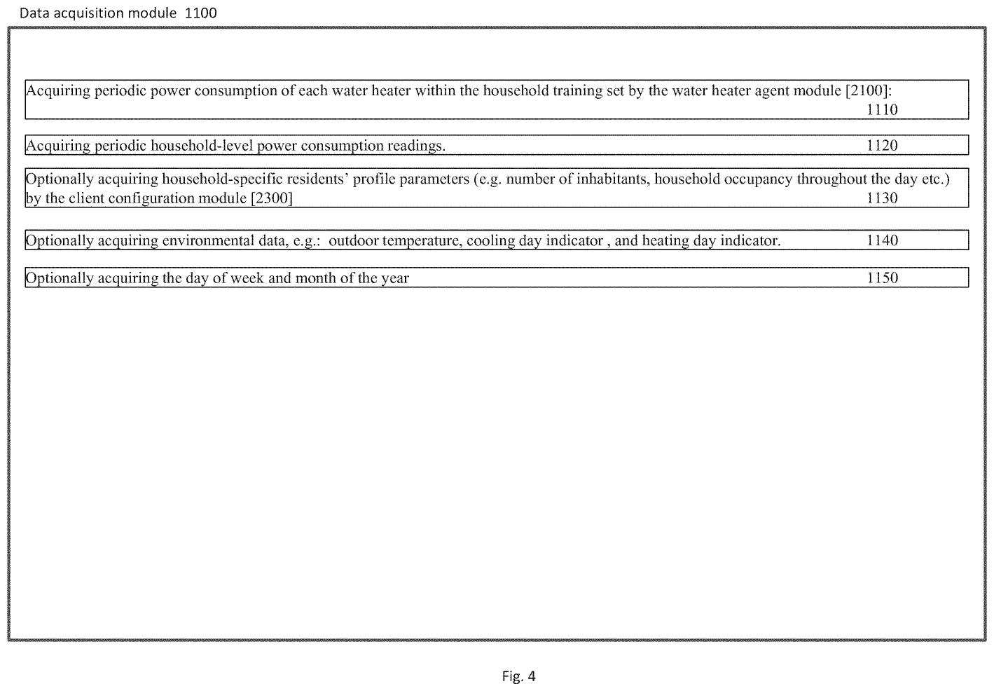

FIG. 4 is a flow diagram, depicting the function of the data acquisition module 1100 according to some embodiments of the present invention. This module resides within the server 100, and accumulates data pertaining to specific households, both within the household training group and beyond it. The data accumulation module 1100 aggregates and stores at least part of the following data in a database for further analysis:
Data of periodic power consumption per each one of the water heaters is acquired from the water heater agent module [2100], (step 1110).
Optionally Reading of water flow out and/or in from the water tank;
Periodic household-level power consumption readings as acquired by the household power meter interface [2200] (step 1120). According to some embodiments, the household power meter interface [2200] Obtains household power consumption readings every 15/30/60 minutes from a smart household power meter.
Household-specific residents' profile parameters (e.g. number of inhabitants, household occupancy during the day) as acquired by the client configuration module [2300] (step 1130).
This information is comprehensively gathered for households that are members of the household training group. Households of the general monitored household group may or may not present the said data, or may only present a subset of the said data.
Environmental data per each household of the general monitored group of households from external sources (e.g., outdoor temperature, cooling day indicator, and heating day indicator) as acquired by the environmental measurement module [2400] (step 1140).
The day of the week and month of the year as acquired by the client alerts module [2500] (step 1150).

According to one embodiment of the present invention, the data acquisition module incorporates an interface to a database, facilitating the query of accumulated data by other components of the server module 1100.

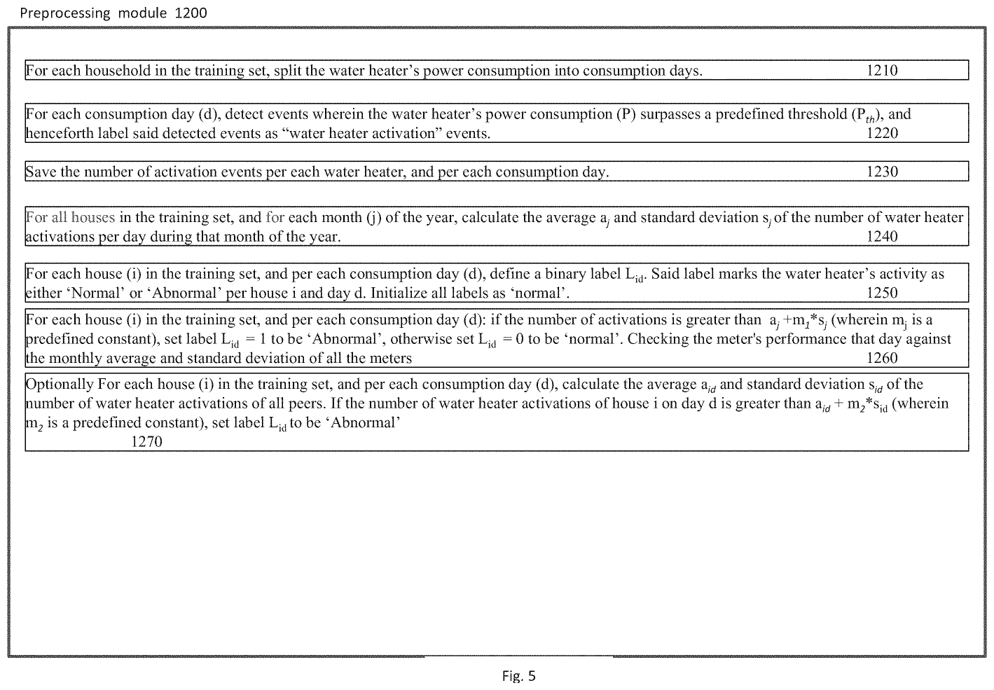

FIG. 5 is a flow diagram, depicting the function of the data preprocessing module 1200 according to some embodiments of the present invention. This module resides within the server 100, and is configured to produce household-specific explanatory features. These explanatory features are later used by the activation events training module 1300A, to classify training group households as ‘efficient’ or ‘inefficient’.

The preprocessing module 1200 splits the water heater's power consumption into consumption days for each household in the training set (step 1210).

The preprocessing module 1200 detects events wherein the water heater's power consumption (P) surpasses a predefined threshold (Pₜₕ), and henceforth labels said detected events as “water heater activation” events for each consumption day (d) (step 1220).

The preprocessing module 1200 saves the number of activation events per each water heater, and per each consumption day (step 1230).

The preprocessing module 1200 calculates the average aⱼ and standard deviation sⱼ of the number of water heater activations per day during that month of the year for all houses in the training set, per each month (j) of the year (step 1240).

The preprocessing module 1200 defines a binary label L_{id} for each house (i) in the training set, and per each consumption day (d). Said label marks the water heater's activity as either ‘Normal’ or ‘Abnormal’ per house i and day d. Initialize all labels as ‘normal’ (step 1250).

The preprocessing module 1200 sets label L_{id}=1, ‘Abnormal’, if the number of activations is greater than aⱼ+m₁*sⱼ (wherein m is a predefined constant for each month j) for each house in the training set, and per each consumption day (d). The preprocessing module 1200 sets label L_{id}=0, ‘normal’, if the number of activations is smaller or equal to aⱼ+m₁*sⱼ set label L_{id}=1 to be ‘Abnormal’, and L_{id}=0 to be ‘normal’. Checking the meter's performance that day against the monthly average and standard deviation of all the meters (step 1260).

The preprocessing module 1200 calculates the average a_{id} and standard deviation s_{id} of the number of water heater activations of all peers for each house (i) in the training set, and per each consumption day (d). If the number of water heater activations of house i on day d is greater than a_{id}+m₂*s_{id} (wherein in is a predefined constant), set label L_{id} to be ‘Abnormal’ (step 1270).

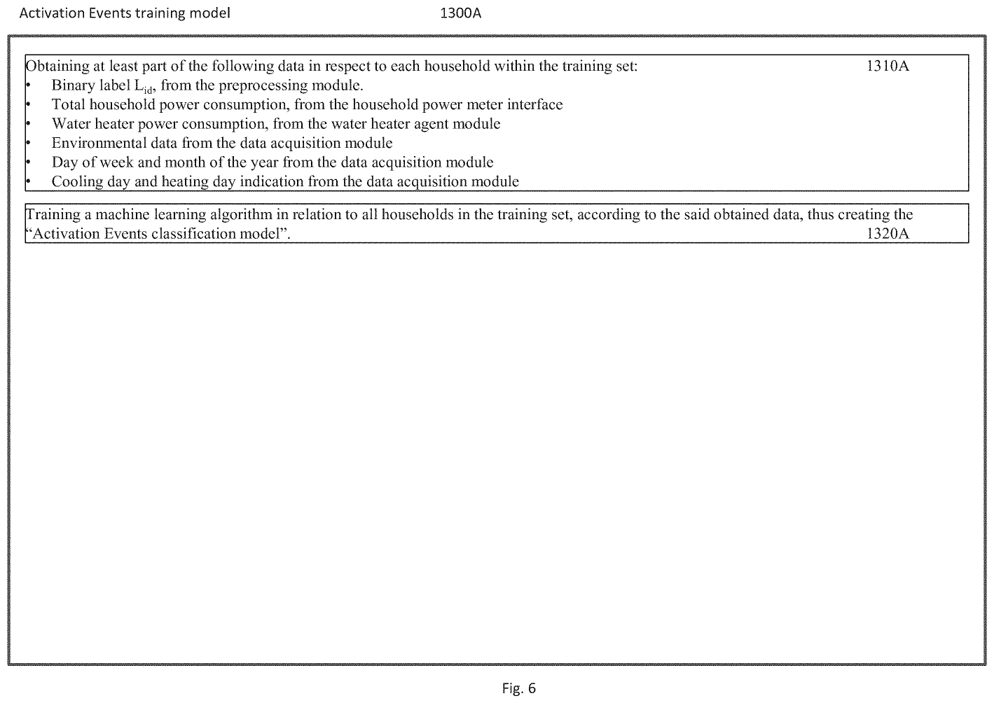

FIG. 6 is a flow diagram, depicting the function of the activation events training module 1300A of first model 1000A according to some embodiments of the present invention.

The activation events training module 1300A obtains at least part of the following data in respect to each household within the training set:
Binary label L_{id}, from the preprocessing module.
Total household power consumption, from the household power meter interface
Water heater power consumption, from the water heater agent module
Environmental data from the data acquisition module
Day of week and month of the year from the data acquisition module
Cooling day and heating day indication from the data acquisition module (step 1310).

A machine learning algorithm is trained in relation to all households in the training set, according to the said obtained data, thus the “Activation Events classification model” is created (step 1320A).

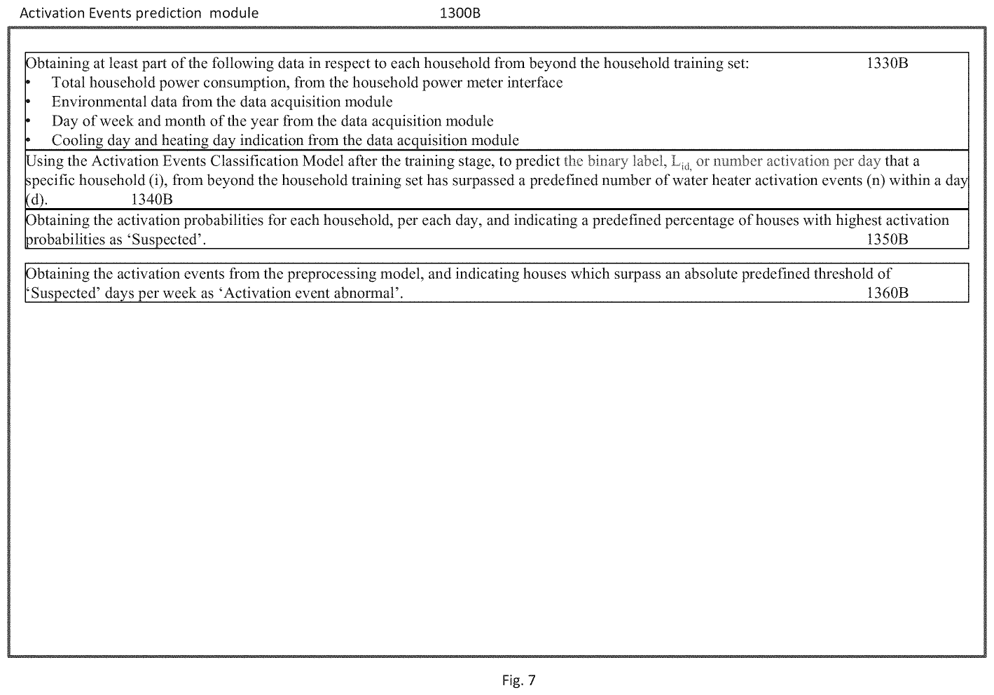

FIG. 7 is a flow diagram, depicting the function of the activation events prediction module 1300B according to some embodiments of the present invention.

The activation events prediction module 1300B obtains at least part of the following data in respect to each household within the training set:
Total household power consumption, from the household power meter interface
Environmental data from the data acquisition module
Day of week and month of the year from the data acquisition module
Cooling day and heating day indication from the data acquisition module (step 1330B)

For example, The Activation Events Classification Model is used after the training stage, to predict the binary label L_{id} or number of activations per day that a specific household (i), from beyond the household training set has surpassed a predefined number of water heater activation events (n) within a day (d) (step 1340B).

The activation probabilities for each household per each day or pre-defined time period, is obtained and a predefined percentage of houses with highest activation probabilities is indicated as ‘Suspected’ (step 1350B). optionally apply machine algorithm for determining the activation probabilities, based on aggregated data for predefined times periods.

The activation events from the preprocessing model are obtained, and houses which surpass an absolute predefined threshold of ‘Suspected’ days per week are indicated as ‘Activation event abnormal’ (step 1360B).

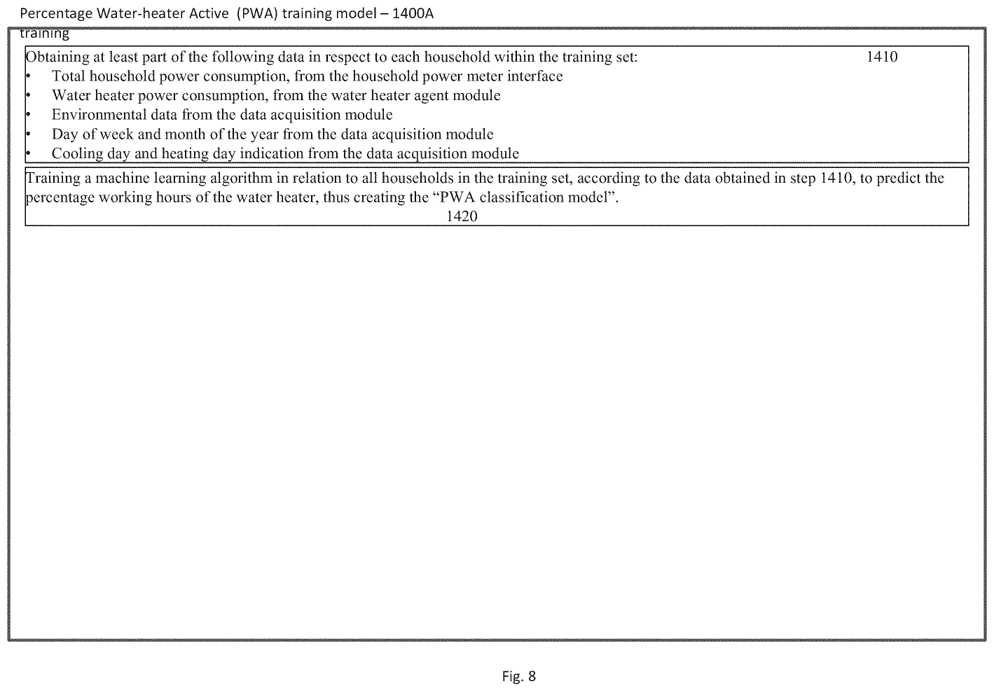

FIG. 8 is a flow diagram, depicting the function of the Percentage Water-heater Active (PWA) training module 1400A of second model 1000B according to some embodiments of the present invention.

This module resides within the server 100, and classifies and uses a model that classifies meters as efficient or inefficient by predicting the percentage of work time of the water heater. Meters with abnormally high work percentage are marked as inefficient and uses a model that classifies meters as efficient or inefficient by predicting the percentage of work time of the water heater. Meters with abnormally high work percentage are marked as inefficient.

The Percentage Water-heater Active (PWA) training module 1400A obtains at least part of the following data in respect to each household within the training set:
Total household power consumption, from the household power meter interface
Water heater power consumption, from the water heater agent module
Environmental data from the data acquisition module
Day of week and month of the year from the data acquisition module
Cooling day and heating day indication from the data acquisition module (step 1410)

A machine learning algorithm is trained in relation to all households in the training set, according to the data obtained in step 1410, to predict the percentage working hours of the water heater, thus the “PWA classification model” is created (step 1420).

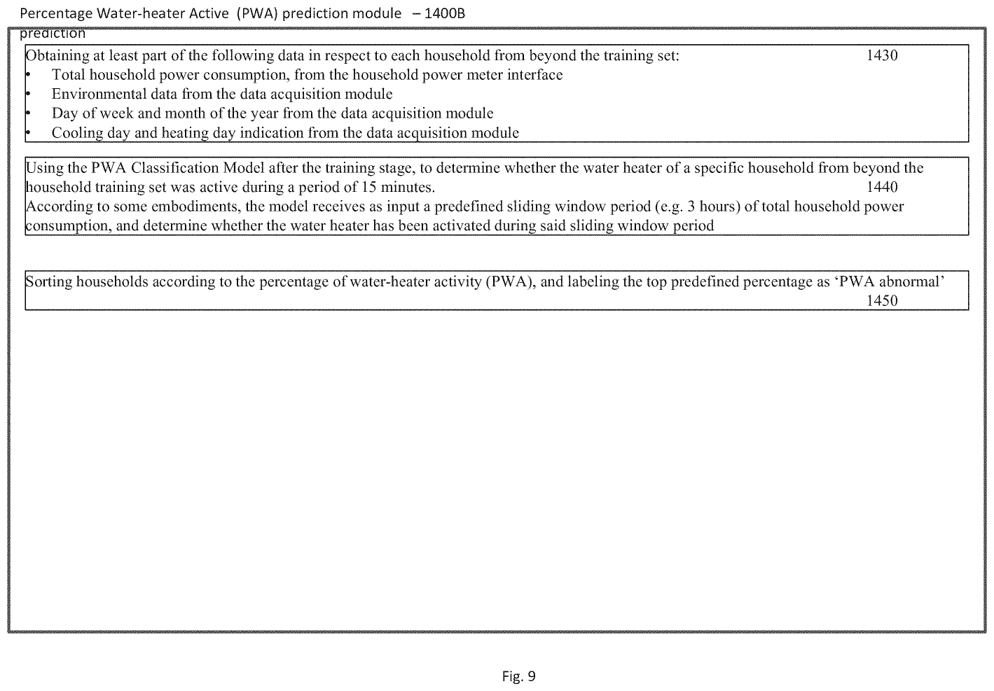

FIG. 9 is a flow diagram, depicting the function of the Percentage Water-heater Active (PWA) prediction module 1400b according to some embodiments of the present invention. The Percentage Water-heater Active (PWA) prediction module 1400b obtains at least part of the following data in respect to each household from beyond the training set:
Total household power consumption, from the household power meter interface
Environmental data from the data acquisition module
Day of week and month of the year from the data acquisition module
Cooling day and heating day indication from the data acquisition module (step 1430)

Optionally according to some embodiments of the present invention instead of the PWA model can be used PWAN (Percentage Water heater Active at night) by applying the same training and prediction process of the PWA with differentiated measurement between day and night time periods.

The PWA Classification Model is used after the training stage to determine whether the water heater of a specific household from beyond the household training set was active during a period of 15 minutes (step 1440). According to some embodiments, the model receives as input a predefined sliding window period (e.g. 3 hours) of total household power consumption and determines whether the water heater has been activated during said sliding window period.

Households are sorted according to the percentage of water-heater activity (PWA), and the top predefined percentage is labeled as ‘PWA abnormal’ (step 1450).

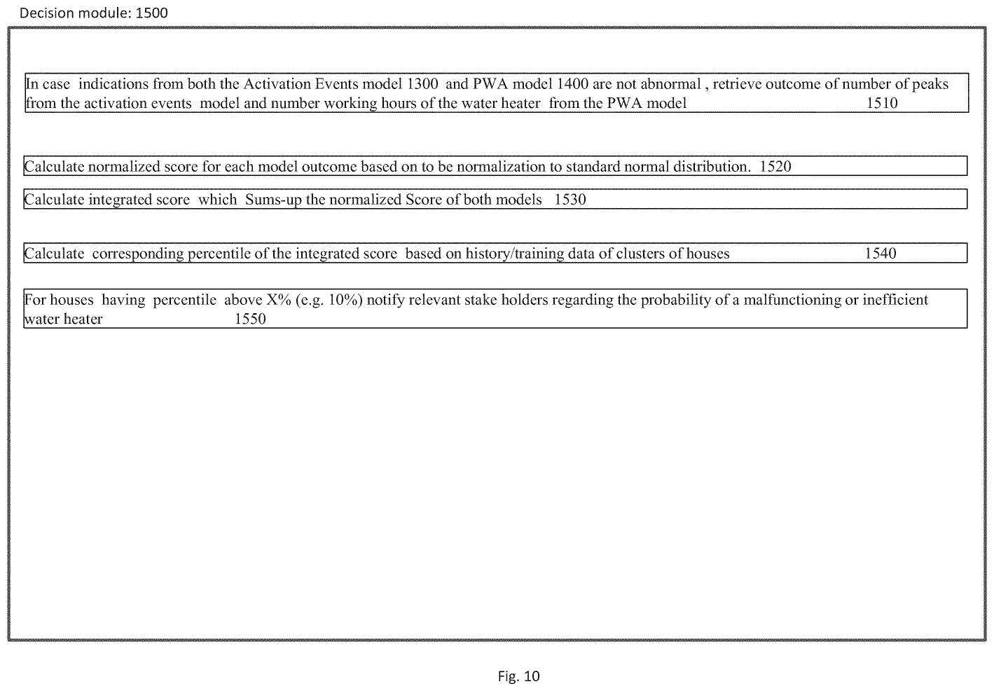

FIG. 10 is a flow diagram, depicting the functionality of the decision module 1500 according to some embodiments of the present invention.

This module resides within the server 100, and applies the following steps:
Incase indications from both the Activation Events model 1300 and PWA model are not abnormal, retrieve outcome of number of picks from the activation events model and number working hours of the water heater from the PWA model (step 1510).
Calculate normalized score for each model outcome based on to be normalization to standard normal distribution (step 1520).
Calculate integrated score is based on any combination according to pre-defined rules of scores such as which Sum-up the normalized Score of both models (step 1530); optionally the score is calculated not by summing up but based on one of the models score or any combination of scores, according to predefine decision rules.
Calculate corresponding percentile of the integrated score base on history/training data of clusters of houses (step 1540).
Optionally a house can be determent as owning inefficient water heater if—the metric of PWA or PWAN are abnormal for example if we compare it to its peers
Optionally for houses having percentile above X % (e.g. 10%) notifying relevant stake holders regarding the probability of a malfunctioning or inefficient water heater (step 1560)

The system of the present invention may include, according to certain embodiments of the invention, machine readable memory containing or otherwise storing a program of instructions which, when executed by the machine, implements some or all of the apparatus, methods, features and functionalities of the invention shown and described herein. Alternatively or in addition, the apparatus of the present invention may include, according to certain embodiments of the invention, a program as above which may be written in any conventional programming language, and optionally a machine for executing the program such as but not limited to a general purpose computer which may optionally be configured or activated in accordance with the teachings of the present invention. Any of the teachings incorporated herein may wherever suitable operate on signals representative of physical objects or substances.

Unless specifically stated otherwise, as apparent from the following discussions, it is appreciated that throughout the specification discussions, utilizing terms such as, “processing”, “computing”, “estimating”, “selecting”, “ranking”, “grading”, “calculating”, “determining”, “generating”, “reassessing”, “classifying”, “generating”, “producing”, “stereo-matching”, “registering”, “detecting”, “associating”, “superimposing”, “obtaining” or the like, refer to the action and/or processes of a computer or computing system, or processor or similar electronic computing device, that manipulate and/or transform data represented as physical, such as electronic, quantities within the computing system's registers and/or memories, into other data similarly represented as physical quantities within the computing system's memories, registers or other such information storage, transmission or display devices. The term “computer” should be broadly construed to cover any kind of electronic device with data processing capabilities, including, by way of non-limiting example, personal computers, servers, computing system, communication devices, processors (e.g. digital signal processor (DSP), microcontrollers, field programmable gate array (FPGA), application specific integrated circuit (ASIC), etc.) and other electronic computing devices.

The present invention may be described, merely for clarity, in terms of terminology specific to particular programming languages, operating systems, browsers, system versions, individual products, and the like. It will be appreciated that this terminology is intended to convey general principles of operation clearly and briefly, by way of example, and is not intended to limit the scope of the invention to any particular programming language, operating system, browser, system version, or individual product.

It is appreciated that software components of the present invention including programs and data may, if desired, be implemented in ROM (read only memory) form including CD-ROMs, EPROMs and EEPROMs, or may be stored in any other suitable typically non-transitory computer-readable medium such as but not limited to disks of various kinds, cards of various kinds and RAMs. Components described herein as software ma y, alternatively, be implemented wholly or partly in hardware, if desired, using conventional techniques. Conversely, components described herein as hardware may, alternatively, be implemented wholly or partly in software, if desired, using conventional techniques.

Included in the scope of the present invention, inter alia, are electromagnetic signals carrying computer-readable instructions for performing any or all of the steps of any of the methods shown and described herein, in any suitable order; machine-readable instructions for performing any or all of the steps of any of the methods shown and described herein, in any suitable order; program storage devices readable by machine, tangibly embodying a program of instructions executable by the machine to perform any or all of the steps of any of the methods shown and described herein, in any suitable order; a computer program product comprising a computer useable medium having computer readable program code, such as executable code, having embodied therein, and/or including computer readable program code for performing, any or all of the steps of any of the methods shown and described herein, in any suitable order; any technical effects brought about by any or all of the steps of any of the methods shown and described herein, when performed in any suitable order; any suitable apparatus or device or combination of such, programmed to perform, alone or in combination, any or all of the steps of any of the methods shown and described herein, in any suitable order; electronic devices each including a process or/and a cooperating input device and/or output device and operative to perform in software any steps shown and described herein; information storage devices or physical records, such as disks or hard drives, causing a computer or other device to be configured so as to carry out any or all of the steps of any of the methods shown and described herein, in any suitable order; a program pre-stored e.g. in memory or on an information network such as the Internet, before or after being downloaded, which embodies any or all of the steps of any of the methods shown and described herein, in any suitable order, and the method of uploading or downloading such, and a system including server/s and/or client's for using such; and hardware which performs any or all of the steps of any of the methods shown and described herein, in any suitable order, either alone or in conjunction with software. Any computer-readable or machine-readable media described herein is intended to include non-transitory computer- or machine-readable media.

Any computations or other forms of analysis described herein may be performed by a suitable computerized method. Any step described herein may be computer-implemented. The invention shown and described herein may include (a) using a computerized method to identify a solution to any of the problems or for any of the objectives described herein, the solution optionally include at least one of a decision, an action, a product, a service or any other information described herein that impacts, in a positive manner, a problem or objectives described herein; and (b) outputting the solution.

The scope of the present invention is not limited to structures and functions specifically described herein and is also intended to include devices which have the capacity to yield a structure, or perform a function, described herein, such that even though users of the device may not use the capacity, they are, if they so desire, able to modify the device to obtain the structure or function.

Features of the present invention which are described in the context of separate embodiments may also be provided in combination in a single embodiment.

For example, a system embodiment is intended to include a corresponding process embodiment. Also, each system embodiment is intended to include a server-centered “view” or client centered “view”, or “view” from any other node of the system, of the entire functionality of the system, computer-readable medium, apparatus, including only those functionalities performed at that server or client or node.

1. A method for automatic detection of inefficient household water heater within a group of monitored households, implemented by a server module and a plurality of household client modules, wherein each of said server module and plurality of household client modules comprising one or more processors, operatively coupled to non-transitory computer readable storage devices, on which are stored modules of instruction code, wherein execution of said instruction code by said one or more processors implements the following actions:
acquiring data related to each monitored household for generating a training set, including at least one of environmental conditions, power consumption of each water heater, power consumption of each household, household profile parameters, and household residents' profile parameters; and
for each house (i) in the training set, and per each pre-defined period (d), defining the water heater's activity as either ‘Normal’ or ‘Abnormal’ per house i and day d, based on statistic data water heater activity,
training a machine learning algorithm to create at least one:
classification model for predicting the water heater's activity as either ‘Normal’ or ‘Abnormal’, wherein all monitored households are classified according to said acquired data and parameters; or
regression model for predicting the water heater's activity duration and times, wherein all monitored households are determent according to said acquired data and parameters;
detecting inefficient household water heater(s), after the training period using the regression or Classification Model to, by predicting the water heater activity as normal or abnormal based on acquired data including at least one of environmental conditions, power consumption of the total household, household profile parameters, and household residents' profile parameters.

2. The method of claim 1, wherein defining activity as normal or ab normal is based on comparison of the given house to other related house within the house cluster, wherein cluster is define by houses that are similar houses in the given house vicinity that are mostly similar to the house profile, consumption load and other criteria as house size and appliance ownership.

3. The method of claim 1, wherein the determination of water heater's activity as either ‘Normal’ or ‘Abnormal is based on “Activation Events” Neural Network detecting events by labeling water heater for each house (i) in the training set, and per each consumption day (d), defining a binary label Lid, said label marks the water heater's activity as either ‘Normal’ or ‘Abnormal’ per house i and day d.

4. The method of claim 1, wherein the determination of water heater's activity as either ‘Normal’ or ‘Abnormal is based on Percentage Water-heater Activation” (PWA) Neural Network model to predict the percentage working hours of the water heater, wherein the water heater's power consumption (P) surpasses a predefined threshold (Pth), and henceforth label said detected events as “water heater activation” events.

5. The method of claim 2, further comprising integrating prediction results of the classification the events detection classification and a PWA classification model to detect the inefficient household heater.

6. The method of claim 2, wherein said data obtainable for use with the Activation Events Classification Model comprises at least one of:
total household power consumption, from the household power meter interface;
water heater power consumption, from the water heater agent module;
environmental data from the data acquisition module;
day of week and month of the year from the data acquisition module;
cooling day and heating day indication from the data acquisition module.

7. The method of claim 1, wherein said predefined period of time is 15 minutes.

8. The method of claim 3, wherein the “Percentage Water-heater Activation” (PWA) Neural Network model receives as input a predefined sliding window period of time of total household power consumption, and determine whether the water heater has been activated during said sliding window period.

9. The method of claim 3, wherein said data obtainable for use with the “Percentage Water-heater Activation” (PWA) Neural Network model comprises at least one of:
total household power consumption, from the household power meter interface;
environmental data from the data acquisition module;
day of week and month of the year from the data acquisition module; and
cooling day and heating day indication from the data acquisition module.

10. The method of claim 4, wherein if indications from both the Activation Events Classification model and the PWA classification model are not abnormal, then, (a) retrieving outcome of number of peaks from the activation events classification model and number of working hours of the water heater from the PWA classification model, (b) calculating normalized score for each model outcome based on to be normalization to standard normal distribution, (c) calculating integrated score which is normalized Score of both models, (d) calculating corresponding percentile of the integrated score based on history/training data of clusters of houses; and (e) for houses having percentile above pre-determined percentage related to its' peers, notifying relevant stake holders regarding the probability of a malfunctioning or inefficient water heater.

11. A system for automatic detection of inefficient household water heater within a group of monitored households, comprising at least one server module and a plurality of household client modules, wherein each of said server module and plurality of household client modules comprising one or more processors, operatively coupled to non-transitory computer readable storage devices, on which are stored modules of instruction code, wherein the module comprises:
data acquisition module for acquiring data related to each monitored household for generating a training set, including at least one of environmental conditions, power consumption of each water heater, power consumption of each household, household profile parameters, and household residents' profile parameters; and
training module for each house (i) in the training set, and per each consumption day (d), defining a the water heater's activity as either ‘Normal’ or ‘Abnormal’ per house i and day d, based on statistic data water heater activity and training a machine learning algorithm to create at least one classification model for predicting the water heater's activity as either ‘Normal’ or ‘Abnormal’, wherein all monitored households are classified according to said acquired data and parameters; and
prediction module for detecting inefficient household water heater(s), after the training period using the Classification Model to, by predicting the water heater activity as normal or abnormal based on acquired data including at least one of environmental conditions, power consumption of each household, household profile parameters, and household residents' profile parameters and weather conditions.

12. The system of claim 11, wherein the determination of water heater's activity as either ‘Normal’ or ‘Abnormal is based on comparison of the given house to other related house with in the house cluster, wherein cluster is define by houses that are similar houses in the given house vicinity that are mostly similar to the house profile, consumption load and other criteria as house size and appliance ownership.

13. The system of claim 12, wherein the determination of water heater's activity as either ‘Normal’ or ‘Abnormal is based on “Activation Events” Neural Network detecting events by labeling water heater for each house (i) in the training set, and per each consumption day (d), defining a binary label Lid, said label marks the water heater's activity as either ‘Normal’ or ‘Abnormal’ per house i and day d.

14. The system of claim 11, wherein the determination of water heater's activity as either ‘Normal’ or ‘Abnormal is based on Percentage Water-heater Activation” (PWA) Neural Network model to predict the percentage working hours of the water heater, wherein the water heater's power consumption (P) surpasses a predefined threshold (Pth), and henceforth label said detected events as “water heater activation” events.

15. The system of claim 12, wherein the prediction results of the classification the events detection classification and a PWA classification model are integrated to detect the inefficient household water heater.

16. The system of claim 12, wherein said data obtainable for use with the Activation Events Classification Model comprises at least one of:
total household power consumption, from the household power meter interface;
water heater power consumption, from the water heater agent module training data set;
environmental data from the data acquisition module;
day of week and month of the year from the data acquisition module;
cooling day and heating day indication from the data acquisition module.

17. The system of claim 11, wherein said predefined period of time is 15 minutes.

18. The system of claim 13, wherein the “Percentage Water-heater Activation” (PWA) Neural Network model receives as input a predefined sliding window period of time of total household power consumption, and determine whether the water heater has been activated during said sliding window period.

19. The system of claim 13, wherein said data obtainable for use with the “Percentage Water-heater Activation” (PWA) Neural Network model comprises at least one of:
total household power consumption, from the household power meter interface;
environmental data from the data acquisition module;
day of week and month of the year from the data acquisition module; and
cooling day and heating day indication from the data acquisition module.

20. The system of claim 11, further comprising a decision module, wherein if indications from both the Activation Events Classification model and the PWA classification model are not abnormal, said decision module (a) retrieves outcome of number of peaks from the activation events classification model and number of working hours of the water heater from the PWA classification model, (b) calculates normalized score for each model outcome by normalization to standard normal distribution, (c) calculates integrated score which Sums-up the normalized Score of both models, (d) calculates corresponding percentile of the integrated score based on history/training data of clusters of houses; and (e) for houses having percentile above X % relative to its peers notifies relevant stake holders regarding the probability of a malfunctioning or inefficient water heater.

21. The method of claim 1, further comprising the step of checking the existence of water heater pre-processing groups of households of historical consumption of water heater based actual measurement performed by sensors associated with said water heater in relation to profile of household including characteristics of the household and/or lifestyle of the occupant and environmental time dependent parameters, and determining the probability of said water heater at the surveyed household based on identified profile parameters and actual behavior pattern of the analyzed household based on sampled measurement in relation to actual time dependent environmental parameters of the relevant time period, by processing identified statistical correlations between presence of appliances at each household and 1) household profiles parameters, 2) household actual periodic consumption pattern 3) household actual periodic consumption pattern in relation to environmental time dependent parameters.
